(19) United States
(12) Patent Application Publication
(10) Pub. No.: US 2026/0182124 A1
(43) Pub. Date: Jun. 25, 2026

(54) DISPLAY DEVICE

(71) Applicant: LG Display Co., Ltd., Seoul (KR)

(72) Inventors: Jinhyeon YUN, Paju-si (KR); Yuseop SHIN, Bucheon-si (KR); Kiyong HONG, Paju-si (KR); Kiyoung SONG, Paju-si (KR); Jihyun KOO, Seoul (KR); Byungyeon CHOI, Goyang-si (KR)

(73) Assignee: LG Display Co., Ltd., Seoul (KR)

(21) Appl. No.: 19/312,060

(22) Filed: Aug. 27, 2025

(30) Foreign Application Priority Data
Dec. 24, 2024 (KR) 10-2024-0195581

(51) Int. Cl. H10H 29/85; H10H 29/856

(52) U.S. Cl. CPC H10H 29/8517; H10H 29/856

(57) ABSTRACT

A display device according to an exemplary embodiment of the present disclosure includes a substrate, a plurality of light emitting elements disposed on the substrate, and a plurality of filters disposed between adjacent light emitting elements of the plurality of light emitting elements. Each filter includes an inner filter configured to selectively transmit a wavelength, an outer filter covering the inner filter and having a lower refractive index than the inner filter, a filter reflective layer covering the outer filter to reflect visible light, and an antireflection layer disposed on at least one side surface of the filter reflective layer to allow transmission in a desired direction. By directing light from neighboring elements toward a target element and reflecting light that would otherwise be lost, the arrangement improves light emission efficiency and enhances image quality.

### CROSS-REFERENCE TO RELATED APPLICATIONS

This application claims the priority of Korean Patent Application No. 10-2024-0195581 filed on Dec. 24, 2024, in the Korean Intellectual Property Office, the disclosure of which is incorporated herein by reference.

### BACKGROUND

### Technical Field

The present disclosure relates to a display device, and more particularly, to a display device with improved light emission efficiency.

### Description of the Related Art

Display devices used in computer monitors, televisions, and mobile phones include an organic light emitting display (OLED) device, which emits light by itself, and a liquid crystal display (LCD) device, which requires a separate light source.

The application range of display devices is diversifying not only to computer monitors and televisions but also to personal portable devices, and research is underway on display devices having a large display area while achieving reduced volume and weight.

In addition, in recent years, display devices including light emitting diodes (LEDs) have attracted attention as next-generation display devices. Since LEDs are made of inorganic materials, not organic materials, they exhibit superior reliability and have longer lifespan compared to liquid crystal display devices and organic light emitting display devices. Furthermore, LEDs not only have fast lighting speed, but also exhibit excellent light emission efficiency, high impact resistance and superior stability, and can display high-brightness images.

### BRIEF SUMMARY

The disclosed display device introduces a novel optical structure that enhances the efficiency of light emission in microLED pixels, particularly red subpixels, which traditionally suffer from reduced luminous efficiency. By placing specialized filters between adjacent subpixels, light emitted from green and blue elements is selectively transmitted into the red element, effectively providing an auxiliary light source in addition to the red element's own emission. This approach directly addresses the well-known efficiency droop in red microLEDs caused by sidewall defects and non-radiative recombination.

Each filter is a multilayer structure including an inner filter, an outer filter with a lower refractive index, a reflective layer, and an antireflection layer. This arrangement ensures that green or blue light can pass toward the red subpixel while concurrently reflecting red light back upward, preventing lateral losses. Asymmetric filter thicknesses further optimize wavelength selectivity between red-green and red-blue subpixel boundaries, ensuring balanced color performance and efficient light utilization.

Additional reflective layers placed on the sidewalls of pixel-defining banks further redirect stray light back toward the active emission areas, reinforcing the efficiency gains. Combined, these design elements improve light extraction and overall image quality while reducing power consumption.

The configuration lies in the integration of selective transmission and reflective recycling mechanisms that direct light from neighboring subpixels into the red subpixel while also preventing lateral light loss. By allowing green and blue light to act as an additional source for the red subpixel, overall emission efficiency is increased beyond what is achieved by current injection alone. This optical arrangement also reflects red light that would otherwise escape sideways, redirecting it upward to improve light extraction. As a result, the red subpixel, which is typically less efficient due to material limitations and sidewall effects, achieves higher luminous performance.

Together, these mechanisms provide a display structure that improves balance among colors, reduces power consumption, and enhances image quality through more efficient use of emitted light.

For example, various embodiments of the present disclosure provide a display device capable of supplying an additional light source to adjacent light emitting elements.

Various embodiments of the present disclosure provide a display device with improved light emission efficiency of light emitting elements.

Technical benefits of the present disclosure are not limited to the above-mentioned benefits, and other benefits, which are not mentioned above, can be clearly understood by those skilled in the art from the following descriptions.

A display device according to an exemplary embodiment of the present disclosure includes a substrate, a plurality of light emitting elements disposed on the substrate, and a plurality of filters disposed between the plurality of light emitting elements, in which each of the plurality of filters includes an inner filter, an outer filter disposed to cover the inner filter and having a lower refractive index than the inner filter, a filter reflective layer disposed to cover the outer filter, and an antireflection layer disposed on at least one side surface of the filter reflective layer.

A display device according to another exemplary embodiment of the present disclosure includes a substrate, a green light emitting element and a blue light emitting element disposed on the substrate, and a red light emitting element disposed between the green light emitting element and the blue light emitting element, a first filter disposed between the red light emitting element and the green light emitting element and transmitting at least a portion of light emitted from the green light emitting element to the red light emitting element, and a second filter disposed between the red light emitting element and the blue light emitting element and transmitting at least a portion of light emitted from the blue light emitting element to the red light emitting element.

Other detailed matters of the exemplary embodiments are included in the detailed description and the drawings.

According to the present disclosure, light extraction efficiency of the light emitting element can be improved.

According to the present disclosure, an additional light source may be provided from the green light emitting element and the blue light emitting element to the red light emitting element, so that light emission efficiency of the red light emitting element can be improved.

According to the present disclosure, light efficiency of the light emitting element may be improved, so that high-quality images can be provided with lower power consumption.

The effects according to the present disclosure are not limited to the contents exemplified above, and more various effects are included in the present disclosure.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary embodiment of the present disclosure;

FIG. 2 is a vertical cross-sectional view of a pixel of a display device according to an exemplary embodiment of the present disclosure;

FIGS. 3A to 3G are process diagrams for explaining a method of manufacturing a display device according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

As used herein, the phrase “at least one of A, B, and C” encompasses any of A, B, or C individually, as well as any combination of two or more of A, B, and C together. Thus, the phrase covers embodiments that include only A, only B, or only C, embodiments that include A and B together, A and C together, or B and C together, and embodiments that include A, B, and C together. Unless otherwise expressly stated, the phrase does not imply any order, priority, or exclusivity among the listed elements, and the elements may be present in any suitable form, structure, or combination consistent with the context.

The features of various embodiments of the present disclosure can be partially or entirely adhered to or combined with each other and can be interlocked and operated in technically various ways, and the embodiments can be carried out independently of or in association with each other.

Hereinafter, an exemplary embodiments of the present disclosure will be described in detail with reference to accompanying drawings.

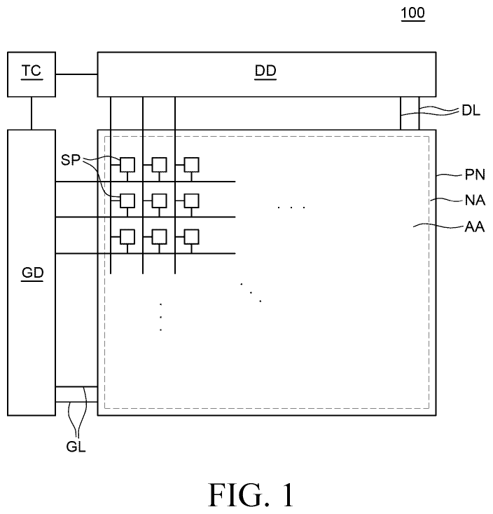

FIG. 1 is a schematic diagram of a display device according to an exemplary embodiment of the present disclosure.

In FIG. 1, for convenience of explanation, only a display panel PN, a gate driver GD, a data driver DD, and a timing controller TC among various configurations of a display device 100 are illustrated.

Referring to FIG. 1, the display device 100 includes a display panel PN that includes a plurality of sub-pixels SP, a gate driver GD and a data driver DD that supply various signals to the display panel PN, and a timing controller TC that controls the gate driver GD and the data driver DD.

The gate driver GD supplies a plurality of scan signals to a plurality of gate lines GL according to a plurality of gate control signals provided from the timing controller TC.

In FIG. 1, one gate driver GD is illustrated as being disposed spaced apart on one side of the display panel PN, but the number and disposition of the gate driver GD are not limited thereto.

The data driver DD converts image data input from the timing controller TC into data voltages using reference gamma voltages according to a plurality of data control signals provided from the timing controller TC. The data driver DD may supply the converted data voltages to a plurality of data lines DL.

The timing controller TC aligns image data input from the outside and supplies it to the data driver DD. The timing controller TC may generate gate control signals and data control signals using synchronization signals input from the outside, for example, a dot clock signal, a data enable signal, and horizontal/vertical synchronization signals. The timing controller TC may supply the generated gate control signals and data control signals to the gate driver GD and the data driver DD, respectively, and control the gate driver GD and the data driver DD.

The display panel PN is a configuration for displaying images to a user and includes a plurality of sub-pixels SP. In the display panel PN, a plurality of gate lines GL and a plurality of data lines DL intersect each other, and each of the plurality of sub-pixels SP is connected to the gate lines GL and the data lines DL. In addition, although not shown in the drawings, each of the plurality of sub-pixels SP may be connected to a high potential power line, a low potential power line, or a reference line.

In the display panel PN, an active area AA and a non-active area NA that encloses the active area AA may be defined.

The active area AA is an area where images are displayed in the display device 100. A plurality of sub-pixels SP constituting a plurality of pixels and circuits for driving the plurality of sub-pixels SP may be disposed in the active area AA. The plurality of sub-pixels SP are the smallest units constituting the active area AA, and n sub-pixels SP may form one pixel. Each of the plurality of sub-pixels SP may include a light emitting element and a thin film transistor for driving the light emitting element. The plurality of light emitting elements may be defined differently depending on the type of the display panel PN. For example, when the display panel PN is an inorganic light emitting display panel PN, the light emitting element may be a light emitting diode (LED) or a micro light emitting diode (micro LED).

A plurality of signal lines for transmitting various signals to the plurality of sub-pixels SP may be disposed in the active area AA. For example, the plurality of signal lines may include a plurality of data lines DL that supply data voltages to each of the plurality of sub-pixels SP, and a plurality of gate lines GL that supply gate voltages to each of the plurality of sub-pixels SP. The plurality of gate lines GL may extend in one direction in the active area AA and be connected to the plurality of sub-pixels SP, and the plurality of data lines DL may extend in a direction different from the one direction in the active area AA and be connected to the plurality of sub-pixels SP. In addition, low potential power lines, high potential power lines, and the like may further be disposed in the active area AA, but the present disclosure is not limited thereto.

The non-active area NA is an area where images are not displayed and may be defined as an area extending from the active area AA. The non-active area NA may include link wirings for transmitting signals to the sub-pixels SP of the active area AA, and driving ICs such as pad electrodes, a gate driver IC, and a data driver IC.

Meanwhile, the non-active area NA may be located on the rear surface of the display panel PN, that is, on a surface where there are no sub-pixels SP, or may be omitted, and is not limited to what is illustrated in the drawings.

Meanwhile, driving units such as the gate driver GD, the data driver DD, and the timing controller TC may be connected to the display panel PN in various ways. For example, the gate driver GD may be mounted in the non-active area NA in a GIP (gate in panel) method or may be mounted between the plurality of sub-pixels SP in the active area AA in a GIA (gate in active area) method. For example, the data driver DD and the timing controller TC may be formed on separate flexible films and printed circuit boards and may be electrically connected to the display panel PN by bonding the flexible films and printed circuit boards to pad electrodes formed in the non-active area NA of the display panel PN. If the gate driver GD is mounted using the GIP method and the data driver DD and the timing controller TC transmit signals to the display panel PN through pad electrodes of the non-active area NA, it is necessary to secure an area of the non-active area NA for disposing the gate driver GD and the pad electrodes, and the bezel may increase.

In contrast, when the gate driver GD is mounted inside the active area AA using the GIA method and side lines are formed to connect signal lines on the front surface of the display panel PN to pad electrodes on the rear surface of the display panel PN, and flexible films and printed circuit boards are bonded to the rear surface of the display panel PN, the non-active area NA on the front surface of the display panel PN may be minimized. That is, when the gate driver GD, the data driver DD, and the timing controller TC are connected to the display panel PN in this manner, it is possible to achieve a zero bezel implementation in which the bezel is substantially eliminated, but the present disclosure is not limited thereto.

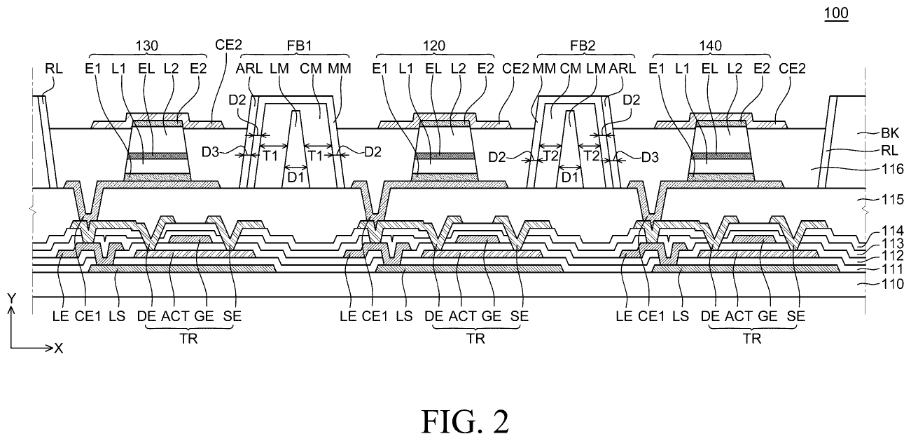

FIG. 2 is a vertical cross-sectional view of a pixel of a display device according to an exemplary embodiment of the present disclosure.

Referring to FIG. 2, the display device 100 according to an exemplary embodiment of the present disclosure includes a substrate 110, a buffer layer 111, a gate insulating layer 112, a first interlayer insulating layer 113, a second interlayer insulating layer 114, a first planarization layer 115, a second planarization layer 116, a plurality of transistors TR, a plurality of light emitting elements 120, 130, and 140, a first connection electrode CE1, a second connection electrode CE2, a light shielding layer LS, an auxiliary electrode LE, a bank BK, a plurality of filters FB1 and FB2, and a reflective layer RL.

Referring to FIG. 2, the substrate 110 is a configuration for supporting various components included in the display device 100 and may be made of an insulating material. For example, the substrate 110 may be made of glass or resin. In addition, the substrate 110 may be formed of a material including a polymer or plastic and may be made of a material having flexibility.

A light shielding layer LS may be disposed on the substrate 110. The light shielding layer LS may block light incident to the active layer ACT of the plurality of transistors TR from below the substrate 110. Accordingly, light incident from the light shielding layer LS to the active layer ACT of the plurality of transistors TR may be blocked, thereby minimizing leakage current.

A buffer layer 111 may be disposed on the substrate 110 and the light shielding layer LS. The buffer layer 111 may reduce the permeation of moisture or impurities through the substrate 110. For example, the buffer layer 111 may be formed as a single layer or a multilayer of silicon oxide (SiOx) or silicon nitride (SiNx), but is not limited thereto. The buffer layer 111 may also be omitted depending on the type of substrate 110 or the type of transistor and is not limited thereto.

A plurality of transistors TR may be disposed on the buffer layer 111. Each of the plurality of transistors TR may include an active layer ACT, a gate electrode GE, a source electrode SE, and a drain electrode DE. Since the configurations of each of the plurality of transistors TR are substantially the same, one transistor TR will be described as an example below.

An active layer ACT may be disposed on the buffer layer 111. The active layer ACT may be made of a semiconductor material such as an oxide semiconductor, amorphous silicon, or polysilicon, but is not limited thereto.

A gate insulating layer 112 may be disposed on the active layer ACT. The gate insulating layer 112 may be an insulating layer for insulating the active layer ACT and the gate electrode GE. The gate insulating layer 112 may be formed as a single layer or a multilayer of, for example, silicon oxide (SiOx) or silicon nitride (SiNx), but is not limited thereto.

A gate electrode GE may be disposed on the gate insulating layer 112. The gate electrode GE may be electrically connected to the source electrode SE of the transistor TR. The gate electrode GE may be formed of a conductive material such as copper (Cu), aluminum (Al), molybdenum (Mo), nickel (Ni), titanium (Ti), chromium (Cr), or an alloy thereof, but is not limited thereto.

A first interlayer insulating layer 113 and a second interlayer insulating layer 114 may be disposed on the gate electrode GE. Contact holes may be formed in the first interlayer insulating layer 113 and the second interlayer insulating layer 114 so that each of the source electrode SE and the drain electrode DE is connected to the active layer ACT. The first interlayer insulating layer 113 and the second interlayer insulating layer 114 are insulating layers for protecting the configurations below them and may be formed as a single layer or a multilayer of silicon oxide (SiOx) or silicon nitride (SiNx), but are not limited thereto.

A source electrode SE and a drain electrode DE which are electrically connected to the active layer ACT may be disposed on the second interlayer insulating layer 114. The source electrode SE and the drain electrode DE may be formed of a conductive material such as copper (Cu), aluminum (Al), molybdenum (Mo), nickel (Ni), titanium (Ti), chromium (Cr), or an alloy thereof, but are not limited thereto.

Meanwhile, in the present disclosure, it has been described that a first interlayer insulating layer 113 and a second interlayer insulating layer 114, that is, a plurality of insulating layers, are disposed between the gate electrode GE and the source electrode SE and the drain electrode DE, but only one insulating layer may be disposed between the gate electrode GE and the source electrode SE and the drain electrode DE, and the present disclosure is not limited thereto. However, as illustrated in the drawings, when a plurality of insulating layers such as the first interlayer insulating layer 113 and the second interlayer insulating layer 114 are disposed between the gate electrode GE and the source electrode SE and the drain electrode DE, an electrode may additionally be formed between the first interlayer insulating layer 113 and the second interlayer insulating layer 114. The additionally formed electrode may form a capacitor together with another configuration disposed below the first interlayer insulating layer 113 or above the second interlayer insulating layer 114.

An auxiliary electrode LE may be disposed on the gate insulating layer 112. The auxiliary electrode LE may electrically connect the light shielding layer LS below the buffer layer 111 to either the source electrode SE or the drain electrode DE on the second interlayer insulating layer 114. For example, since the light shielding layer LS is electrically connected to either the source electrode SE or the drain electrode DE through the auxiliary electrode LE, it does not operate as a floating gate, thereby minimizing threshold voltage variations of the transistor TR caused by the light shielding layer LS which is floated. In the drawings, the light shielding layer LS is illustrated as being connected to the drain electrode DE, but the light shielding layer LS may also be connected to the source electrode SE, and the present disclosure is not limited thereto.

Although not illustrated in the drawings, a power line may be disposed on the second interlayer insulating layer 114. The power line may be electrically connected to the plurality of light emitting elements 120, 130, and 140 together with the plurality of transistors TR to emit light from the plurality of light emitting elements 120, 130, and 140. The power line may be formed of a conductive material such as copper (Cu), aluminum (Al), molybdenum (Mo), nickel (Ni), titanium (Ti), chromium (Cr), or an alloy thereof, but is not limited thereto.

A first planarization layer 115 may be disposed on the plurality of transistors TR. The first planarization layer 115 may be disposed to cover the source electrode SE and the drain electrode DE. Through this, the first planarization layer 115 may planarize the top surfaces of the configurations disposed below, including the source electrode SE and the drain electrode DE. In addition, the first planarization layer 115 may include one or more contact holes. The first planarization layer 115 may be made of, for example, an organic material such as benzocyclobutene or acryl, but is not limited thereto.

A plurality of first connection electrodes CE1 may be disposed on the first planarization layer 115. Each of the plurality of first connection electrodes CE1 may be connected to the drain electrode DE of each of the plurality of transistors TR through a contact hole formed in the first planarization layer 115. The plurality of first connection electrodes CE1 may also serve as reflective plates. Each of the plurality of first connection electrodes CE1 may be disposed below each of the plurality of light emitting elements 120, 130, and 140, and may reflect light emitted from each of the plurality of light emitting elements 120, 130, and 140 toward the top of the substrate 110. Accordingly, the first connection electrodes CE1 may include various conductive layers in consideration of both light reflection efficiency and resistance. For example, the first connection electrodes CE1 may use an opaque conductive layer such as silver (Ag), aluminum (Al), molybdenum (Mo), titanium (Ti), or alloys thereof together with a transparent conductive layer such as indium tin oxide (ITO), but are not limited thereto. A plurality of light emitting elements 120, 130, and 140 is disposed on the plurality of first connection electrodes CE1, respectively. Each of the plurality of light emitting elements 120, 130, and 140 may be disposed corresponding to each of the plurality of first connection electrodes CE1. Thus, each of the plurality of light emitting elements 120, 130, and 140 may be electrically connected to different transistors TR through the corresponding first connection electrode CE1.

In one pixel, the plurality of light emitting elements 120, 130, and 140 may emit different colors. For example, referring to FIG. 2, the first light emitting element 120 may be a red light emitting element that emits red light. The second light emitting element 130 disposed on one side of the first light emitting element 120 may be a green light emitting element that emits green light. The third light emitting element 140 disposed on the other side of the first light emitting element 120 may be a blue light emitting element that emits blue light. In this case, the first light emitting element 120 may be disposed between the second light emitting element 130 and the third light emitting element 140.

Each of the plurality of light emitting elements 120, 130, and 140 may include a first electrode E1, a first semiconductor layer L1, an emission layer EL, a second semiconductor layer L2, and a second electrode E2. For example, referring to FIG. 2, in each of the plurality of light emitting elements 120, 130, and 140, the first semiconductor layer L1, the emission layer EL, the second semiconductor layer L2, and the second electrode E2 may be sequentially disposed on the first electrode E1. Therefore, the plurality of light emitting elements 120, 130, and 140 may be vertical-type light emitting elements, but are not limited thereto.

A first electrode E1, disposed overlapping the first connection electrode CE1 on the first connection electrode CE1, is an electrode for electrically connecting the transistor TR and the first semiconductor layer L1. The first electrode E1 may be formed of a conductive material, for example, a transparent conductive material such as indium tin oxide (ITO) or indium zinc oxide (IZO), or an opaque conductive material such as titanium (Ti), gold (Au), silver (Ag), copper (Cu), or an alloy thereof, but is not limited thereto. To assist the electrical connection between the first connection electrode CE1 and the first electrode E1, a conductive layer (not shown) may be further disposed between the first connection electrode CE1 and the first electrode E1.

A first semiconductor layer L1 may be disposed on the first electrode E1, and a second semiconductor layer L2 may be disposed on the first semiconductor layer L1. The first semiconductor layer L1 and the second semiconductor layer L2 may be layers formed by doping a specific material with n-type or p-type impurities, respectively. For example, each of the first semiconductor layer L1 and the second semiconductor layer L2 may be a layer formed by doping a material such as gallium nitride (GaN), indium aluminum phosphide (InAlP), or gallium arsenide (GaAs) with p-type or n-type impurities. The p-type impurity may be, for example, magnesium (Mg), zinc (Zn), or beryllium (Be), and the n-type impurity may be, for example, silicon (Si), germanium, or tin (Sn), but they are not limited thereto.

An emission layer EL may be disposed between the first semiconductor layer L1 and the second semiconductor layer L2. The emission layer EL may receive holes and electrons from the first semiconductor layer L1 and the second semiconductor layer L2 to emit light. The emission layer EL may be formed as a single layer or a multi-quantum well (MQW) structure and may be made of, for example, indium gallium nitride (InGaN) or gallium nitride (GaN), but is not limited thereto.

A second electrode E2 may be disposed on the second semiconductor layer L2. The second electrode E2 is an electrode for electrically connecting the second semiconductor layer L2 to the power line. The second electrode E2 may be formed of a conductive material such as a transparent conductive material like indium tin oxide (ITO) or indium zinc oxide (IZO), but is not limited thereto.

Each of the plurality of light emitting elements 120, 130, and 140 may further include an encapsulation layer that encloses each of the plurality of light emitting elements 120, 130, and 140. The encapsulation layer may enclose the first semiconductor layer L1, the emission layer EL, and the second semiconductor layer L2. The encapsulation layer may be made of an insulating material to protect the first semiconductor layer L1, the emission layer EL, and the second semiconductor layer L2. In addition, a contact hole may be formed in the encapsulation layer to expose the first electrode E1 and the second electrode E2 so that the first connection electrode CE1 and the second connection electrode CE2 may be electrically connected to the first electrode E1 and the second electrode E2, respectively. A plurality of filters FB1 and FB2 may be disposed between the plurality of light emitting elements 120, 130, and 140. For example, referring to FIG. 2, a first filter FB1 may be disposed between the first light emitting element 120 and the second light emitting element 130. In addition, a second filter FB2 may be disposed between the first light emitting element 120 and the third light emitting element 140.

Each of the plurality of filters FB1 and FB2 includes an inner filter LM, an outer filter CM, a filter reflective layer MM, and an antireflection layer ARL.

The inner filter LM is disposed at the innermost side of the filter FB1 and FB2. The inner filter LM serves to filter specific wavelengths.

For example, the inner filter LM of the first filter FB1 disposed between the first light emitting element 120 and the second light emitting element 130 may selectively transmit green light. Accordingly, the inner filter LM of the first filter FB1 may selectively block transmission of light of wavelengths other than green light.

In addition, the inner filter LM of the second filter FB2 disposed between the first light emitting element 120 and the third light emitting element 140 may selectively transmit blue light. Accordingly, the inner filter LM of the second filter FB2 may selectively block transmission of light of wavelengths other than blue light.

A maximum width D1 of the inner filter LM in a first direction X may be 2 nm to 15 nm, and preferably 2 nm to 5 nm, but is not limited thereto. The maximum widths D1 of the inner filters LM of the first filter FB1 and the second filter FB2 in the first direction X may be the same. For example, referring to FIG. 2, the sizes of the inner filters LM of the first filter FB1 and the second filter FB2 may be same, but the present disclosure is not limited thereto.

On a vertical cross-section, a height of a top surface of the inner filter LM may be disposed higher than a maximum height of top surfaces of the plurality of light emitting elements 120, 130, and 140. For example, referring to FIG. 2, the height of the top surface of the inner filter LM of the first filter FB1 may be higher than the heights of the top surfaces of the first light emitting element 120 and the second light emitting element 130. In addition, the height of the top surface of the inner filter LM of the second filter FB2 may be higher than the heights of the top surfaces of the first light emitting element 120 and the third light emitting element 130. In the present disclosure, the height refers to a height from the substrate 110.

The inner filter LM may include, for example, germanium (Ge), titanium (Ti), chromium (Cr), and the like, but is not limited thereto.

The outer filter CM serves to select the wavelength to be transmitted together with the inner filter LM. The outer filter CM may have a refractive index smaller than that of the inner filter LM. In addition, the outer filter CM is disposed to completely cover the inner filter LM. For example, referring to FIG. 2, the outer filter CM may be disposed to completely cover the entire side surfaces and top surface of the inner filter LM.

The outer filter CM of the first filter FB1, disposed between the first light emitting element 120 and the second light emitting element 130, may selectively transmit green light together with the inner filter LM. Accordingly, light of wavelengths other than green light may be selectively blocked by the outer filter CM and the inner filter LM of the first filter FB1.

In addition, the outer filter CM of the second filter FB2, disposed between the first light emitting element 120 and the third light emitting element 140, may selectively transmit blue light together with the inner filter LM. Accordingly, light of wavelengths other than blue light may be selectively blocked by the outer filter CM and the inner filter LM of the second filter FB2.

The outer filter CM may have the same thicknesses from both side surfaces of the inner filter LM. Specifically, the thicknesses from one side surface of the inner filter LM to the adjacent side surface of the outer filter CM in the first direction X, and the thicknesses from the other side surface of the inner filter LM to the adjacent other side surface of the outer filter CM in the first direction X may be the same. For example, referring to FIG. 2, in the first filter FB1, the thickness T1 from the right side surface of the inner filter LM to the right side surface of the outer filter CM and the thickness T1 from the left side surface of the inner filter LM to the left side surface of the outer filter CM may be the same. In addition, in the second filter FB2, the thickness T2 from the right side surface of the inner filter LM to the right side surface of the outer filter CM and the thickness T2 from the left side surface of the inner filter LM to the left side surface of the outer filter CM may be the same. Hereinafter, for convenience of explanation, the thickness of the outer filter CM is defined as the thickness from one side surface of the inner filter LM to the adjacent side surface of the outer filter CM.

In addition, the thickness T1 of the outer filter CM of the first filter FB1 and the thickness T2 of the outer filter CM of the second filter FB2 may be different from each other. For example, referring to FIG. 2, the thickness T1 of the outer filter CM of the first filter FB1 may be greater than the thickness T2 of the outer filter CM of the second filter FB2. Accordingly, the maximum width of the outer filter CM of the first filter FB1 in the first direction X may be greater than the maximum width of the outer filter CM of the second filter FB2 in the first direction X.

The thickness T1 of the outer filter CM of the first filter FB1 may be about 90 nm to 100 nm, for example. In addition, the thickness T2 of the outer filter CM of the second filter FB2 may be about 60 nm to 80 nm, for example. However, the thicknesses T1 and T2 of the outer filters CM of the first filter FB1 and the second filter FB2 may vary depending on factors such as the material of the outer filters CM, the material or thickness of the inner filter LM, and so on. For example, the thickness T1 of the outer filter CM of the first filter FB1 may be adjusted according to requirements such as the material or thickness of the inner filter LM to selectively transmit green light together with the inner filter LM. In addition, the thickness T2 of the outer filter CM of the second filter FB2 may be adjusted according to requirements such as the material or thickness of the inner filter LM to selectively transmit blue light together with the inner filter LM.

The outer filter CM of the first filter FB1 and the second filter FB2 may each include at least one of zinc sulfide (ZnS), silicon dioxide (SiO₂), titanium dioxide (TiO₂), and zinc oxide (ZnO). For example, the outer filter CM of the first filter FB1 and the outer filter CM of the second filter FB2 may be made of the same material, but are not limited thereto.

The filter reflective layer MM serves to reflect wavelengths in the visible light region and is disposed to completely cover the outer filter CM. For example, referring to FIG. 2, the filter reflective layer MM of each of the first filter FB1 and the second filter FB2 may be disposed to cover the entire side surfaces and top surface of each outer filter CM.

The thickness D2 from one side surface of the outer filter CM to the adjacent side surface of the filter reflective layer MM may be the same as the thickness D2 from the other side surface of the outer filter CM to the adjacent other side surface of the filter reflective layer MM. For example, the thickness D2 from one side surface of the outer filter CM to the adjacent side surface of the filter reflective layer MM may be 10 nm to 40 nm. For convenience of explanation, hereinafter, the thickness of the filter reflective layer MM is defined as the thickness from one side surface of the outer filter CM to the adjacent side surface of the filter reflective layer MM. The thickness D2 of the filter reflective layer MM of the first filter FB1 and the thickness D2 of the filter reflective layer MM of the second filter FB2 may be the same, but are not limited thereto.

The filter reflective layer MM may include a metal material that easily reflects visible light wavelengths. For example, the filter reflective layer MM may include metal materials such as silver (Ag), gold (Au), or aluminum (Al), but is not limited thereto. The filter reflective layer MM of the first filter FB1 and the filter reflective layer MM of the second filter FB2 may be made of the same material, but are not limited thereto.

The filter reflective layer MM may lose its reflective function at the interface in contact with the outer filter CM due to the outer filter CM. Therefore, while the outer surface of the filter reflective layer MM reflects visible light, its internal interface in contact with the outer filter CM may allow visible light to pass through.

An antireflection layer ARL is disposed on at least one side surface of the filter reflective layer MM. The antireflection layer ARL is disposed on one side surface of the filter reflective layer MM and may cause the reflective function of the filter reflective layer to be lost. Accordingly, visible light may not be reflected but transmitted at the side surface of the filter reflective layer MM where the antireflection layer ARL is disposed.

The antireflection layer ARL may include the same material as the outer filter CM. For example, the antireflection layer ARL may include one or more of zinc sulfide (ZnS), silicon dioxide (SiO₂), titanium dioxide (TiO₂), and zinc oxide (ZnO).

Referring to FIG. 2, in the first filter FB1 disposed between the first light emitting element 120 and the second light emitting element 130, the antireflection layer ARL may be disposed to face the second light emitting element 130. Accordingly, since the reflective function of the filter reflective layer MM at the surface facing the second light emitting element 130 is lost due to the antireflection layer ARL, light emitted from the second light emitting element 130 toward the first filter FB1 may pass through the filter reflective layer MM. Thus, the light emitted from the second light emitting element 130 may pass through the first filter FB1 and reach the first light emitting element 120. In contrast, on the surface of the filter reflective layer MM of the first filter FB1 facing the first light emitting element 120, the antireflection layer ARL may not be disposed. Therefore, light emitted from the first light emitting element 120 may be reflected by the filter reflective layer MM facing it and may not pass through the first filter FB1 and may be reflected.

In addition, in the second filter FB2 disposed between the first light emitting element 120 and the third light emitting element 140, the antireflection layer ARL may be disposed to face the third light emitting element 140. Accordingly, since the reflective function of the filter reflective layer MM at the surface facing the third light emitting element 140 is lost due to the antireflection layer ARL, light emitted from the third light emitting element 140 toward the second filter FB2 may pass through the filter reflective layer MM. Thus, the light emitted from the third light emitting element 140 may pass through the second filter FB2 and reach the first light emitting element 120. In contrast, on the surface of the filter reflective layer MM of the second filter FB2 facing the first light emitting element 120, the antireflection layer ARL may not be disposed. Therefore, the light emitted from the first light emitting element 120 may be reflected by the filter reflective layer MM facing it and may not pass through the second filter FB2 and may be reflected.

The thickness D3 from one side surface of the filter reflective layer MM to the adjacent side surface of the antireflection layer ARL may be 30 nm to 50 nm. For convenience of explanation, hereinafter, the thickness D3 of the antireflection layer ARL is defined as the thickness from one side surface of the filter reflective layer MM to the adjacent side surface of the antireflection layer ARL. The thickness D3 of the antireflection layer ARL of the first filter FB1 and that of the second filter FB2 may be the same, but are not limited thereto.

Banks BK may be disposed on the opposite side of the first filter FB1 with respect to the second light emitting element 130 and on the opposite side of the second filter FB2 with respect to the third light emitting element 140. The banks BK may partition a pixel area including the plurality of light emitting elements 120, 130, and 140.

Referring to FIG. 2, the first filter FB1 may be disposed on one side of the second light emitting element 130, and a bank BK may be disposed on the opposite side of the first filter FB1, that is, on the other side of the second light emitting element 130. In addition, the second filter FB2 may be disposed on one side of the third light emitting element 140, and a bank BK may be disposed on the opposite side of the second filter FB2, that is, on the other side of the third light emitting element 140. As such, with respect to one pixel, the bank BK may be disposed at the outer periphery of the pixel.

The bank BK may include an organic insulating material. For example, the bank BK may be formed of at least one of acrylic resin, epoxy resin, phenol resin, polyamide resin, polyimide resin, unsaturated polyester resin, polyphenylene resin, polyphenylene sulfide resin, benzocyclobutene, and photoresist, but is not limited thereto.

The bank BK may be made of the same material as the first planarization layer 115. In addition, the bank BK may be integrated with the first planarization layer 115, but is not limited thereto.

A plurality of reflective layers RL may be disposed on a side surface of the bank BK.

The plurality of reflective layers RL may be disposed to face the second light emitting element 130 and the third light emitting element 140, respectively. For example, referring to FIG. 2, a reflective layer RL may be disposed on a side surface of the bank BK facing the second light emitting element 130. In addition, a reflective layer RL may be disposed on a side surface of the bank BK facing the third light emitting element 140.

The reflective layer RL may include a metal material with high reflectivity. For example, the reflective layer RL may include metal materials such as silver (Ag), gold (Au), or aluminum (Al), but is not limited thereto.

A second planarization layer 116 may be disposed on the first planarization layer 115 and the first connection electrode CE1. The second planarization layer 116 may be disposed to enclose the side surfaces of the plurality of light emitting elements 120, 130, and 140. In addition, the second planarization layer 116 may be disposed to fill the spaced areas between the plurality of light emitting elements 120, 130, and 140 and the bank BK, the first filter FB1, and the second filter FB2. For example, referring to FIG. 2, the second planarization layer 116 may be disposed in the spaced areas between the first light emitting element 120 and the first filter FB1 and between the first light emitting element 120 and the second filter FB2. The second planarization layer 116 may also be disposed in the spaced areas between the second light emitting element 130 and the bank BK and between the second light emitting element 130 and the first filter FB1. Furthermore, the second planarization layer 116 may be disposed in the spaced areas between the third light emitting element 140 and the bank BK and between the third light emitting element 140 and the second filter FB2. Accordingly, the second planarization layer 116 may planarize the upper portion of the substrate 110 on which the plurality of light emitting elements 120, 130, and 140 is disposed and may secure the plurality of light emitting elements 120, 130, and 140 on their respective first connection electrodes CE1. The second planarization layer 116 may also expose the top surfaces of the plurality of light emitting elements 120, 130, and 140. The second planarization layer 116 may be made of, for example, a photoresist or an acrylic-based organic material, but is not limited thereto.

A plurality of second connection electrodes CE2 may be disposed on the top surfaces of the plurality of light emitting elements 120, 130, and 140 exposed by the second planarization layer 116. The second connection electrodes CE2 may electrically connect the plurality of light emitting elements 120, 130, and 140 to the power line.

The second connection electrodes CE2 may be disposed to cover the upper portions of the plurality of light emitting elements 120, 130, and 140 exposed from the second planarization layer 116. Accordingly, the second connection electrodes CE2 may be electrically connected to the second electrodes E2 and the second semiconductor layers L2 of each of the plurality of light emitting elements 120, 130, and 140.

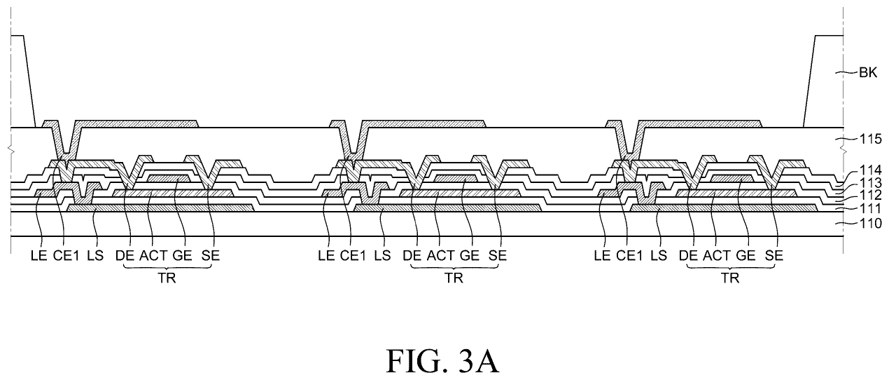

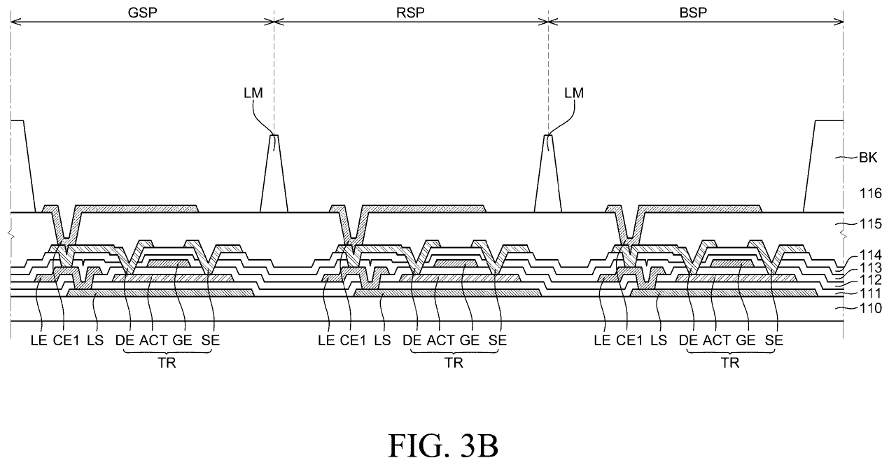

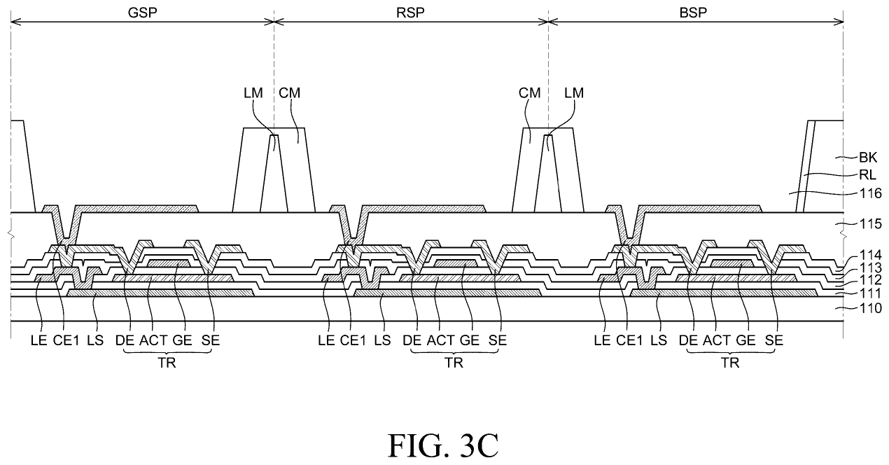

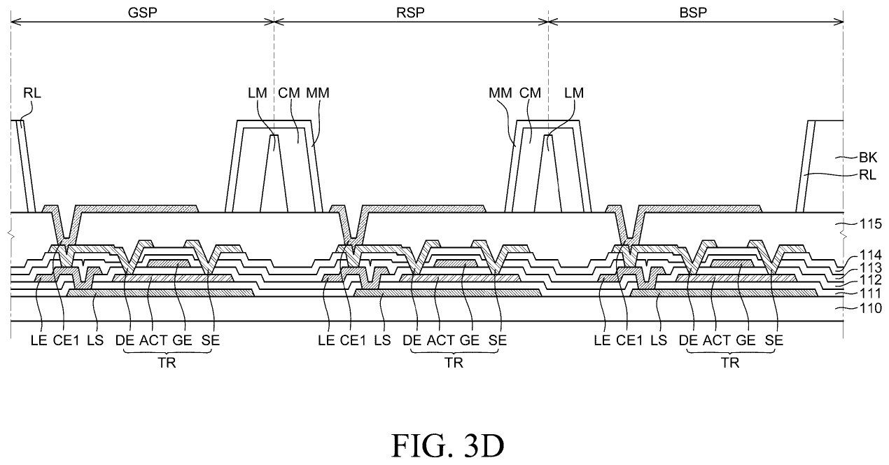

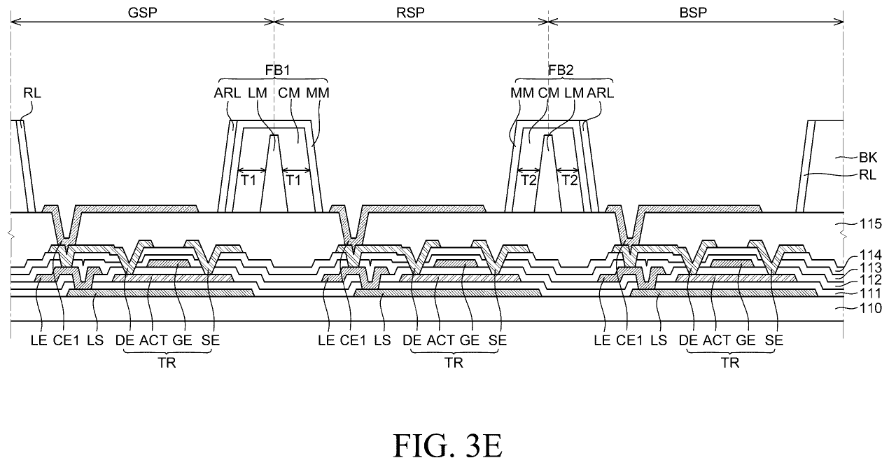

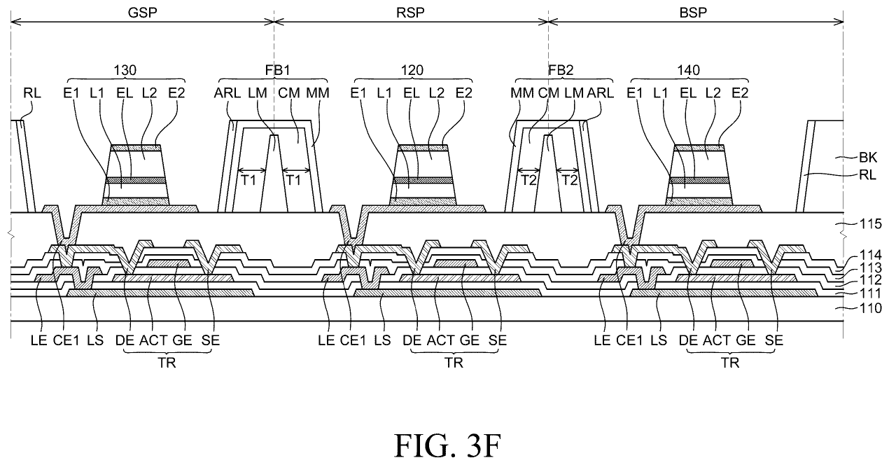

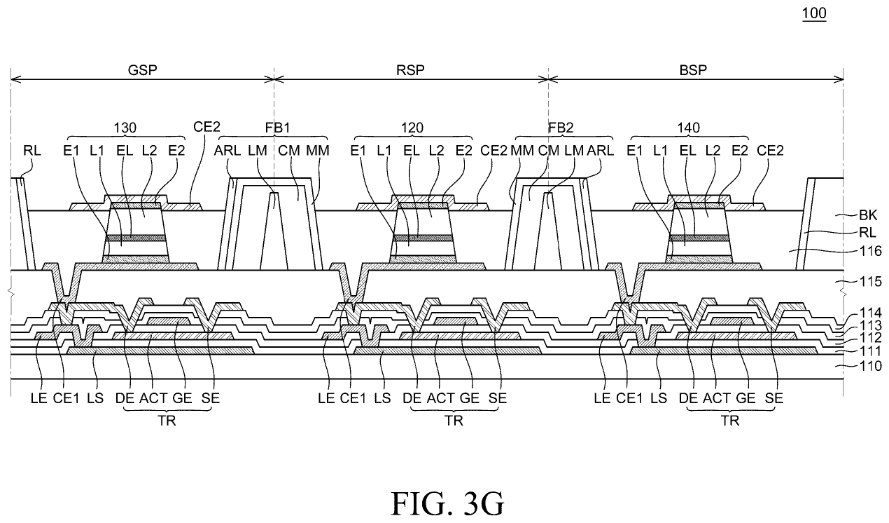

Hereinafter, a method of manufacturing the display device 100 according to an exemplary embodiment of the present disclosure will be described with reference to FIGS. 3A to 3G.

FIGS. 3A to 3G are process diagrams for explaining a method of manufacturing a display device according to an exemplary embodiment of the present disclosure.

Referring to FIG. 3A, a plurality of transistors TR is disposed on the substrate 110, and the top surfaces of the plurality of transistors TR are planarized by covering them with the first planarization layer 115. Then, a plurality of spaced banks BK is formed on the first planarization layer 115. The bank BK may define one pixel. In this case, the bank BK may be made of the same material as the first planarization layer 115, but is not limited thereto. At this time, at least a portion of the top surface of the first planarization layer 115 may be exposed by the plurality of spaced banks BK. In this manner, the first planarization layer 115 exposed by the plurality of banks BK may form one pixel.

In this manner, in one pixel, a plurality of contact holes is formed in the first planarization layer 115 exposed by the bank BK to expose a portion of each drain electrode DE of each of the plurality of transistors TR for forming red, green, and blue sub-pixels. Then, a plurality of first connection electrodes CE1 is disposed on the first planarization layer 115 so as to correspond to each of the plurality of contact holes. In this case, each of the plurality of first connection electrodes CE1 is connected to the drain electrode DE of each of the plurality of transistors TR through the contact hole of the first planarization layer 115. In addition, the plurality of first connection electrodes CE1 is disposed on the first planarization layer 115 so as to be spaced from each other.

Referring to FIG. 3B, the inner filters LM are deposited on portions of the plurality of first connection electrodes CE1 in one pixel where they are spaced from each other. At this time, the inner filter LM is disposed to be spaced from the first connection electrode CE1. Accordingly, the inner filters LM are not electrically connected to the plurality of transistors TR. In this manner, the one pixel may be divided into three sub-pixel areas RSP, GSP, and BSP by the plurality of inner filters LM. In this case, the area formed at the center of one pixel may be a red sub-pixel RSP, the area formed on the left side with respect to the red sub-pixel RSP may be a green sub-pixel GSP, and the area formed on the right side with respect to the red sub-pixel RSP may be a blue sub-pixel BSP. However, this is not limited thereto, and a blue sub-pixel BSP may be formed on the left side with respect to the red sub-pixel RSP and a green sub-pixel GSP may be formed on the right side. The plurality of inner filters LM may have the same size. Here, the same size means that both the width in the first direction X and the height in the second direction Y are identical.

Referring to FIG. 3C, a plurality of outer filters CM is deposited to correspond to each of the inner filters LM in one pixel. In this case, each of the plurality of outer filters CM is disposed to completely cover each of the plurality of inner filters LM. The thicknesses T1 and T2 of the plurality of outer filters CM formed in one pixel may differ from each other. Specifically, the thickness T1 of the outer filter CM disposed between the red subpixel RSP and the green sub-pixel GSP and the thickness T2 of the outer filter CM disposed between the red sub-pixel RSP and the blue subpixel BSP, may be different from each other as illustrated in FIG. 2. For example, the thickness T1 in the first direction X of the outer filter CM disposed between the red sub-pixel RSP and the green sub-pixel GSP may be greater than the thickness T2 in the first direction X of the outer filter CM disposed between the red sub-pixel RSP and the blue sub-pixel BSP.

Referring to FIG. 3D, a plurality of filter reflective layers MM is deposited to correspond to each of the plurality of outer filters CM. Each of the plurality of filter reflective layers MM is formed to completely cover each of the plurality of outer filters CM. However, the plurality of filter reflective layers MM is disposed to be spaced from the plurality of first connection electrodes CE1. In addition, in one pixel, the reflective layers RL are also deposited on the side surfaces of the banks BK facing the filter reflective layers MM. For example, the reflective layers RL may be deposited on the side surfaces of the banks BK disposed on one side of the green sub-pixel GSP and one side of the blue sub-pixel BSP, respectively. In this case, the reflective layer RL formed on one side of the green sub-pixel GSP may be disposed to face the inside of the green sub-pixel GSP. Likewise, the reflective layer RL formed on one side of the blue sub-pixel BSP may be disposed to face the inside of the blue sub-pixel BSP. The reflective layer RL and the filter reflective layer MM may be formed of the same material, but are not limited thereto.

Referring to FIG. 3E, an antireflection layer ARL is deposited on one side surface of each of the plurality of filter reflective layers MM. Specifically, in the filter reflective layer MM disposed between the red sub-pixel RSP and the green sub-pixel GSP, the antireflection layer ARL is deposited on the one surface facing the green sub-pixel GSP. In contrast, in the filter reflective layer MM disposed between the red sub-pixel RSP and the green sub-pixel GSP, the one surface facing the red sub-pixel RSP does not have an antireflection layer ARL deposited thereon. In addition, in the filter reflective layer MM disposed between the red sub-pixel RSP and the blue sub-pixel BSP, the antireflection layer ARL is deposited on the one surface facing the blue sub-pixel BSP. In contrast, in the filter reflective layer MM disposed between the red sub-pixel RSP and the blue sub-pixel BSP, the one surface facing the red sub-pixel RSP does not have an antireflection layer ARL deposited thereon. By depositing the antireflection layers ARL in this manner, a plurality of filters FB1 and FB2 may be disposed between each of the sub-pixels RSP, GSP, and BSP.

Next, referring to FIG. 3F, in each sub-pixel RSP, GSP, and BSP, a plurality of light emitting elements 120, 130, and 140 is transferred onto each of the first connection electrodes CE1. Specifically, the first light emitting element 120 is disposed on the first connection electrode CE1 of the red sub-pixel RSP. In addition, the second light emitting element 130 is disposed on the first connection electrode CE1 of the green sub-pixel GSP, and the third light emitting element 140 is disposed on the first connection electrode CE1 of the blue sub-pixel BSP. In this case, the first light emitting element 120 may be a red light emitting element that emits red light, the second light emitting element 130 may be a green light emitting element that emits green light, and the third light emitting element 140 may be a blue light emitting element that emits blue light.

Finally, referring to FIG. 3G, a material for forming the second planarization layer 116 may be applied so as to enclose the side surfaces of each of the plurality of light emitting elements 120, 130, and 140. Specifically, in the red sub-pixel RSP, the second planarization layer 116 may be formed to fill the spaced area between the first light emitting element 120 and the first filter FB1, and between the first light emitting element 120 and the second filter FB2. In addition, in the green sub-pixel GSP, the second planarization layer 116 may be formed to fill the spaced area between the second light emitting element 130 and the bank BK, and between the second light emitting element 130 and the first filter FB1. Further, in the blue sub-pixel BSP, the second planarization layer 116 may be formed to fill the spaced area between the third light emitting element 140 and the bank BK, and between the third light emitting element 140 and the second filter FB2. A part of the top surface of the second planarization layer 116 may be etched to expose the upper portions of the plurality of light emitting elements 120, 130, and 140. Accordingly, the second electrodes E2 of each of the plurality of light emitting elements 120, 130, and 140 may be exposed by the second planarization layer 116. On the exposed second electrodes E2 of the plurality of light emitting elements 120, 130, and 140, second connection electrodes CE2 are disposed. The second connection electrodes CE2 connect the plurality of light emitting elements 120, 130, and 140 to the power line.

Meanwhile, the light emitting element (for example, LED) is a semiconductor light emitting element that emits light when a current is supplied to the semiconductor, and is made of compound semiconductors such as gallium arsenide (GaAs) or gallium nitride (GaN). Due to the properties of inorganic materials, a high current may be injected, enabling high luminance, and since a low-power-consumption display device may be implemented, LEDs are widely used in various display devices. Recently, technology for manufacturing high-resolution display devices using micro LEDs has been developed. Micro LEDs offer excellent current spreading, enabling effective injection of current into the active layer inside the LED, thereby providing advantages such as higher light output per unit area and current density compared to large-area LEDs.

In the case of micro LEDs, compared to conventional large-area LEDs, the ratio of the exposed sidewall area to the light-emitting area increases, and due to surface defect states present at the sidewalls, non-radiative recombination, in which electron-hole pairs fail to recombine properly, rapidly increases, causing problems such as the generation of leakage current. This leads to a decrease in external quantum efficiency (EQE) as the current density increases, resulting in an efficiency droop phenomenon.

As the size of the micro LEDs decreases, the ratio of the exposed sidewall area to the light-emitting area increases. Therefore, the probability of non-radiative recombination and leakage current occurring at the sidewalls also increases. In particular, this issue occurs more severely in red light emitting elements than in green and blue light emitting elements due to differences in the materials used for each micro LED. Specifically, red light emitting elements exhibit a more significant decrease in luminous efficiency because they have a higher diffusion rate than green and blue light emitting elements.

Accordingly, a display device 100 according to an exemplary embodiment of the present disclosure includes filters disposed between the plurality of light emitting elements 120, 130, and 140. Specifically, in the display device 100 according to an exemplary embodiment of the present disclosure, a first filter FB1 is disposed between the first light emitting element 120, which is a red light emitting element, and the second light emitting element 130, which is a green light emitting element. In addition, a second filter FB2 is disposed between the first light emitting element 120 and the third light emitting element 140, which is a blue light emitting element. In this case, the first filter FB1 may selectively transmit green light among the light emitted from the second light emitting element 130 to the first light emitting element 120. Likewise, the second filter FB2 may selectively transmit blue light among the light emitted from the third light emitting element 140 to the first light emitting element 120. In this manner, green light and blue light emitted from the second light emitting element 130 and the third light emitting element 140, respectively, may be incident on the first light emitting element 120. The green and blue light incident on the first light emitting element 120 may serve as a light source for the first light emitting element 120. Thus, in addition to the photon generation by current injection, additional photon generation may be induced in the first light emitting element 120 due to the incident light source from the surroundings. Accordingly, in the display device 100 according to an exemplary embodiment of the present disclosure, the emission efficiency of the first light emitting element 120, which is a red light emitting element, may be improved.

In addition, in the display device 100 according to an exemplary embodiment of the present disclosure, the first filter FB1 and the second filter FB2 may not have an antireflection layer ARL disposed on the one surface facing the first light emitting element 120. Therefore, light traveling from the first light emitting element 120 toward the first filter FB1 and the second filter FB2 may be reflected upward from the substrate 110 by the filter reflective layer MM. Accordingly, by reflecting the light that would otherwise be lost laterally from the first light emitting element 120 upward from the substrate 110, the emission efficiency of the first light emitting element 120 may be further improved.

Further, in the display device 100 according to an exemplary embodiment of the present disclosure, a reflective layer RL may be disposed on one side of the second light emitting element 130 and one side of the third light emitting element 140. As a result, by disposing the reflective layer RL on one side of the second light emitting element 130, light emitted from the second light emitting element 130 in a direction opposite to the first filter FB1 may be reflected upward from the substrate 110 by the reflective layer RL. Likewise, by disposing the reflective layer RL on one side of the third light emitting element 140, light emitted from the third light emitting element 140 in a direction opposite to the second filter FB2 may be reflected upward from the substrate 110 by the reflective layer RL. Therefore, by reflecting the light that would otherwise be lost laterally from the second light emitting element 130 and the third light emitting element 140 upward from the substrate 110, the emission efficiencies of the second light emitting element 130 and the third light emitting element 140 may also be improved.

In this way, in the display device 100 according to an exemplary embodiment of the present disclosure, as the emission efficiency of the plurality of light emitting elements 120, 130, and 140 is improved, a high-quality image may be realized with lower power consumption.

The exemplary embodiments of the present disclosure can also be described as follows:

According to an aspect of the present disclosure, a display device includes a substrate, a plurality of light emitting elements disposed on the substrate, and a plurality of filters disposed between the plurality of light emitting elements, and each of the plurality of filters includes an inner filter, an outer filter disposed to cover the inner filter and having a refractive index smaller than that of the inner filter, a filter reflective layer disposed to cover the outer filter, and an antireflection layer disposed on at least one side surface of the filter reflective layer.

The antireflection layer may include the same material as the outer filter.

The antireflection layer and the outer filter may include at least one of zinc sulfide (ZnS), silicon dioxide (SiO₂), titanium dioxide (TiO₂), and zinc oxide (ZnO).

The plurality of light emitting elements may include a red light emitting element emitting red light, a green light emitting element disposed on one side of the red light emitting element and emitting green light, and a blue light emitting element disposed on the other side of the red light emitting element and emitting blue light, and the plurality of filters may include a first filter disposed between the red light emitting element and the green light emitting element, and a second filter disposed between the red light emitting element and the blue light emitting element.

A maximum width of the outer filter of the first filter may be greater than a maximum width of the outer filter of the second filter.

The antireflection layer of the first filter may be disposed to face the green light emitting element.

The antireflection layer of the second filter may be disposed to face the blue light emitting element.

The display device may further include a plurality of reflective layers disposed on an opposite side of the red light emitting element with respect to each of the green light emitting element and the blue light emitting element.

On a vertical cross-section, a height of a top surface of the inner filter in each of the plurality of filters may be greater than a maximum height of top surfaces of the plurality of light emitting elements.

A thickness from one side surface of the outer filter to the adjacent side surface of the filter reflective layer may be 10 nm to 40 nm.

A thickness from one side surface of the filter reflective layer to the adjacent side surface of the antireflection layer may be 30 nm to 50 nm.

According to another aspect of the present disclosure, a display device includes a substrate, a green light emitting element and a blue light emitting element disposed on the substrate, and a red light emitting element disposed between the green light emitting element and the blue light emitting element, a first filter disposed between the red light emitting element and the green light emitting element and transmitting at least a portion of light emitted from the green light emitting element to the red light emitting element, and a second filter disposed between the red light emitting element and the blue light emitting element and transmitting at least a portion of light emitted from the blue light emitting element to the red light emitting element.

Each of the first filter and the second filter may include an inner filter, an outer filter disposed to cover the inner filter and having a refractive index smaller than that of the inner filter, a filter reflective layer disposed to cover the outer filter, and an antireflection layer disposed on at least one side surface of the filter reflective layer.

The antireflection layer of the first filter and the antireflection layer of the second filter may be disposed to face the green light emitting element and the blue light emitting element, respectively.

A thickness from one side surface of the inner filter to the adjacent side surface of the outer filter in the first filter may be greater than a thickness from one side surface of the inner filter to the adjacent side surface of the outer filter in the second filter.

The antireflection layer may include the same material as the outer filter.

On a vertical cross-section, a height of a top surface of the inner filter of each of the first filter and the second filter may be greater than a maximum height of top surfaces of the red light emitting element, the green light emitting element, and the blue light emitting element.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate;
a plurality of light emitting elements disposed on the substrate; and
a plurality of filters disposed between adjacent light emitting elements of the plurality of light emitting elements,
wherein each filter of the plurality of filters includes:
an inner filter;
an outer filter disposed to cover the inner filter and having a refractive index smaller than that of the inner filter;
a filter reflective layer disposed to cover the outer filter; and
an antireflection layer disposed on at least one side surface of the filter reflective layer.

2. The display device according to claim 1, wherein the antireflection layer includes a same material as the outer filter.

3. The display device according to claim 2, wherein the antireflection layer and the outer filter include at least one of zinc sulfide (ZnS), silicon dioxide (SiO₂), titanium dioxide (TiO₂), and zinc oxide (ZnO).

4. The display device according to claim 1, wherein the plurality of light emitting elements includes:
a red light emitting element configured to emit red light;
a green light emitting element disposed on one side of the red light emitting element and configured to emit green light; and
a blue light emitting element disposed on the other side of the red light emitting element and configured to emit blue light,
and the plurality of filters includes:
a first filter disposed between the red light emitting element and the green light emitting element; and
a second filter disposed between the red light emitting element and the blue light emitting element.

5. The display device according to claim 4, wherein a maximum width of the outer filter included in the first filter is greater than a maximum width of the outer filter included in the second filter.

6. The display device according to claim 4, wherein the antireflection layer included in the first filter is disposed to face the green light emitting element.

7. The display device according to claim 4, wherein the antireflection layer included in the second filter is disposed to face the blue light emitting element.

8. The display device according to claim 4, further comprising a plurality of reflective layers disposed on an opposite side of the red light emitting element with respect to each of the green light emitting element and the blue light emitting element.

9. The display device according to claim 1, wherein, on a vertical cross-section, a height of a top surface of the inner filter in each of the plurality of filters is greater than a maximum height of top surfaces of the plurality of light emitting elements.

10. The display device according to claim 1, wherein a thickness of a region between n one side surface of the outer filter and the adjacent side surface of the filter reflective layer is 10 nm to 40 nm.

11. The display device according to claim 1, wherein a thickness of a region between one side surface of the filter reflective layer and the adjacent side surface of the antireflection layer is 30 nm to 50 nm.

12. A display device comprising:
a substrate;
a green light emitting element and a blue light emitting element disposed on the substrate, and a red light emitting element disposed between the green light emitting element and the blue light emitting element;
a first filter disposed between the red light emitting element and the green light emitting element and configured to transmit at least a portion of light emitted from the green light emitting element to the red light emitting element; and
a second filter disposed between the red light emitting element and the blue light emitting element and configured to transmit at least a portion of light emitted from the blue light emitting element to the red light emitting element.

13. The display device according to claim 12, wherein each of the first filter and the second filter includes:
an inner filter;
an outer filter disposed to cover the inner filter and having a refractive index smaller than that of the inner filter;
a filter reflective layer disposed to cover the outer filter; and
an antireflection layer disposed on at least one side surface of the filter reflective layer.

14. The display device according to claim 13, wherein the antireflection layer of the first filter and the antireflection layer of the second filter are disposed to face the green light emitting element and the blue light emitting element, respectively.

15. The display device according to claim 13, wherein a thickness from one side surface of the inner filter to the adjacent side surface of the outer filter in the first filter is greater than a thickness from one side surface of the inner filter to the adjacent side surface of the outer filter in the second filter.

16. The display device according to claim 13, wherein the antireflection layer includes a same material as the outer filter.

17. The display device according to claim 12, wherein, on a vertical cross-section, a height of a top surface of the inner filter of each of the first filter and the second filter is greater than a maximum height of top surfaces of the red light emitting element, the green light emitting element, and the blue light emitting element.
